(19) United States
(12) Patent Application Publication
(10) Pub. No.: US 2009/0159958 A1
(43) Pub. Date: Jun. 25, 2009

(54) ELECTRONIC DEVICE INCLUDING A SILICON NITRIDE LAYER AND A PROCESS OF FORMING THE SAME

(75) Inventors: Gwyn R. Jones, Sunnyvale, CA (US); Mark Randolph, San Jose, CA (US)

Correspondence Address: LARSON NEWMAN ABEL & POLANSKY, LLP, 5914 W. COURTYARD DRIVE, SUITE 200, AUSTIN, TX, 78730, US

(73) Assignee: SPANSION LLC, Sunnyvale, CA (US)

(21) Appl. No.: 11/961,757

(22) Filed: Dec. 20, 2007

(51) Int. Cl. H01L 29/792; H01L 21/28

(52) U.S. Cl. 257/324; 438/591; 257/E29.309; 257/E21.18

(57) ABSTRACT

An electronic device can include a silicon nitride layer. In an embodiment, the silicon nitride layer can include boron, grains, or both. The silicon nitride layer may be used as part of a charge storage layer within a nonvolatile memory cell within the electronic device. In a particular embodiment, the boron within the silicon nitride layer may be no greater than approximately 9 atomic % of the layer. The boron can be incorporated into the silicon nitride layer as it is being formed. The layer can be formed using chemical vapor deposition, physical vapor deposition, another suitable formation process, or any combination thereof.

### BACKGROUND

1. Field of the Disclosure

This disclosure relates to electronic devices and processes, and more particularly, to electronic devices including silicon nitride layers and processes of forming them.

2. Description of the Related Art

A nonvolatile memory cell can include a charge storage layer that is capable of storing charge in one state (e.g., programmed), and not store a charge in the opposite state (e.g., erased). Floating gates can be used but are typically unable to store multiple bits of data within a single memory cell because charge can migrate throughout the floating gate. Silicon nitride can be used in the charge storage layer. With silicon nitride, the charge is trapped and does not readily migrate throughout the charge storage layer. The silicon nitride layer typically has a stoichiometric composition (Si₃N₄) and is amorphous (i.e., has no grains).

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a cross-sectional view of a portion of a workpiece after forming an insulating layer over a substrate.

FIG. 2 includes an illustration of a cross-sectional view of the workpiece of FIG. 1 after forming a silicon nitride layer over the insulating layer.

FIG. 3 includes an illustration of a cross-sectional view of the workpiece of FIG. 2 after forming another insulating layer and a conductive layer.

FIG. 4 includes an illustration of a cross-sectional view of the workpiece of FIG. 3 after patterning the conductive layer to form a control gate electrode.

FIG. 5 includes an illustration of a cross-sectional view of the workpiece of FIG. 4 after forming source/drain regions within the substrate.

FIG. 6 includes an illustration of a cross-sectional view of the workpiece of FIG. 5 after forming a substantially completed electronic device.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

An electronic device can include a silicon nitride layer. The silicon nitride layer may be used as part of a charge storage layer within a nonvolatile memory cell within the electronic device. In an embodiment, the silicon nitride layer can include boron, grains, or both. In a particular embodiment, the charge storage layer can include a boron-containing silicon nitride layer that has grains. Charge may be more strongly trapped along grain boundaries of the grains. In another particular embodiment, the boron is incorporated into the silicon nitride layer as it is formed. The boron concentration within the silicon nitride layer may be no greater than approximately 9 atomic % of the layer. The layer can be formed using chemical vapor deposition, physical vapor deposition, another suitable formation process, or any combination thereof.

Attention is now directed to processes of forming an electronic device that includes polishing dissimilar conductive layers over an interlevel dielectric. The information herein is provided to aid in understanding particular details, and is not to limit the present invention.

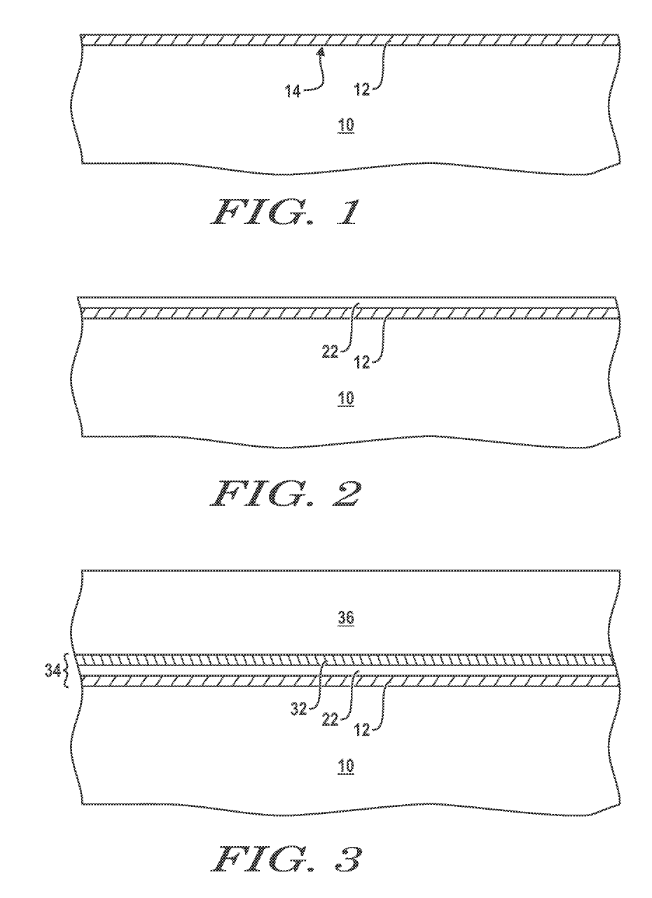

FIG. 1 includes an illustration of a cross-sectional view of a portion of a workpiece that includes a substrate 10. The substrate 10 can include a monocrystalline semiconductor wafer, a semiconductor-on-insulator wafer, a flat panel display (e.g., a silicon layer over a glass plate), or other substrate used to form electronic devices. An insulating layer 12 is formed over the substrate 10. The insulating layer 12 can include silicon dioxide or a high-k (dielectric constant greater than 8) material, such as hafnium oxide, zirconium oxide, another suitable high-k oxide material, or any combination thereof. The insulating layer 12 can act as a gate dielectric layer. In an embodiment, the insulating layer 12 can have a thickness no greater than approximately 20 nm, 15 nm, or 12 nm, and in another embodiment, the insulating layer 12 can have a thickness of at least approximately 1 nm, 3 nm, or 5 nm. In a particular embodiment, the insulating layer has a thickness in a range of approximately 5 nm to approximately 9 nm. The insulating layer 12 can be formed by a conventional or proprietary growth or deposition technique.

FIG. 2 includes an illustration of a cross-sectional view of a portion of the workpiece after forming a silicon nitride layer 22 over the insulating layer 12. The silicon nitride layer 12 can act as a charge storage layer. The thickness of the silicon nitride layer 12 can be any of the thicknesses previously described with respect to the insulating layer 12. The silicon nitride layer 22 and the insulating layer 12 can have the same thickness or different thicknesses.

The silicon nitride layer 12 can include boron. The boron may help to form grains, as silicon nitride is typically an amorphous material. While a theoretical limit on the boron is unknown, other considerations may limit the boron concentration. For example, too much boron may allow some of the boron to diffuse or otherwise migrate to the substrate 10 and affect the doping concentrations therein. A sufficient amount of boron can be incorporated such that grains can form. In an embodiment, the boron concentration within the silicon nitride layer 22 can be no greater than approximately 9 atomic %, 7, atomic %, or 5 atomic %, and in another embodiment, the boron concentration can be at least approximately 0.5 atomic %, 1 atomic %, or 2 atomic %. In a particular embodiment, the insulating layer has a thickness in a range of approximately 2 atomic % to approximately 3 atomic %. In a particular embodiment, the boron concentration within the silicon nitride layer, as formed, is substantially uniform.

The ratio of silicon to nitrogen atoms within the silicon nitride layer 22 can be approximately the same as it is for stoichiometric silicon nitride. The silicon nitride layer 22 can be slightly silicon-rich or nitrogen-rich. In a particular embodiment, the silicon nitride layer 22 can have approximately 3.0 atoms of silicon for every 4.0 atoms of nitrogen.

The silicon nitride layer 22 can be formed by a deposition technique. More specifically, the silicon nitride layer 22 can be formed by chemical vapor deposition (with or without plasma assistance), physical vapor deposition, or the like. When chemical vapor deposition is used, the deposition can be performed using a nitrogen-containing gas, a silicon-containing gas, and a boron-containing gas.

The nitrogen-containing gas can include molecular nitrogen (N₂), ammonia (NH₃), hydrazine (N₂H₄), another suitable nitrogen source, or any combination thereof. The silicon-containing gas can include a compound having the formula below.

SiₐH_{b}X_{c},

wherein X is a halogen (Cl, Br, I or the like), a is 1 to 3, (b+c)=(2a+2), and b or c can be as low as 0 (i.e., H or X not present in the compound). An exemplary compound can include dichlorosilane (SiH₂Cl₂), silane (SiH₄), or disilane (Si₂H₆). The boron-containing gas can include a compound having the formula below.

B_{d}HₑX_{f},

wherein X is a halogen (Cl, Br, I or the like), d is 1 or 2, (e+f)=3d, and e or f can be as low as 0 (i.e., H or X not present in the compound). An exemplary compound can include diborane (B₂H₆), boron tribromide (BBr₃), or boron trichloride (BCl₃). After reading this specification, skilled artisans will appreciate other gases may be used. If needed or desired, a diluent can be added. The diluent can include a noble gas, such as argon, neon, helium, or the like.

When the silicon nitride layer 22 is formed by chemical vapor deposition, the processing conditions may depend on the gases used, whether the reaction is to be plasma assisted or not plasma assisted, the size of the workpiece or the deposition chamber, and the like. If the silicon nitride layer 22 is formed using SiH₂Cl₂, NH₃, and B₂H₆, the deposition temperature can be in a range of approximately 700° C. to approximately 800° C. If SiH₄ is used instead of SiH₂Cl₂, the deposition temperature may be in a range of approximately 600° C. to approximately 700° C., and if Si₂H₆ is used instead of SiH₂Cl₂, the deposition temperature may be in a range of approximately 500° C. to approximately 600° C. When the reaction is plasma assisted, the deposition temperature can be in a range of approximately 200° C. to approximately 400° C. for the silicon-containing gases previously mentioned in this paragraph.

Regardless whether the deposition is plasma assisted or not, the deposition pressure can be in a range of approximately 50 mTorr to approximately 500 mTorr. The gas flow rates and power (if plasma assisted) are principally a function of the size of the workpiece, the deposition chamber, or both. The ratio of the silicon-containing gas and nitrogen-containing gas may be similar to what are typically used when forming a substantially boron-free, stoichiometric silicon nitride layer. In a particular embodiment, a skilled artisan may use processing conditions for making stoichiometric silicon nitride and adding a sufficient amount of a boron-containing gas to achieve the desired boron concentration.

In another embodiment, the silicon nitride layer 22 can be formed by a physical vapor deposition. A target can be generated that has the desired composition of the silicon nitride layer 22. Material from the target can be sputtered onto the workpiece until the desired thickness is achieved. Ions from a noble gas (helium, neon, argon, or the like) can be directed to the target when sputtering the boron-containing silicon nitride material from the target. A workpiece holder (e.g., a chuck) may or may not be heated during the deposition. If needed or desired, the silicon nitride layer 22 may be annealed before forming another layer over the silicon nitride layer.

FIG. 3 includes an illustration of a cross-sectional view of a portion of the workpiece after forming an insulating layer 32 and a conductive layer 36. The insulating layer can include any of the compositions and thicknesses and can be formed using any of the techniques described with respect to the insulating layer 12. The compositions, thicknesses, and formation techniques for the insulating layers 12 and 32 may be the same or different. The charge storage stack 34 includes the insulating layers 12 and 32 and the silicon nitride layer 22.

The conductive layer 36 can be used to form gate electrodes. The conductive layer 36 can include doped silicon, a metal, a metal nitride, another suitable gate electrode material, or any combination thereof. In an embodiment, the conductive layer 36 can have a thickness no greater than approximately 900 nm, 500 nm, or 200 nm, and in another embodiment, the conductive layer 36 can have a thickness of at least approximately 20 nm, 50 nm, or 150 nm. In a particular embodiment, the conductive layer 36 has a thickness in a range of approximately 50 nm to approximately 200 nm. The conductive layer 36 is formed using a conventional or proprietary deposition technique. A hard mask or antireflective layer (not illustrated) can be formed over the conductive layer if needed or desired. The hard mask or antireflective layer can include a nitride or an oxynitride. In a particular embodiment, the hard mask or antireflective layer can include silicon oxynitride, silicon-rich silicon nitride, titanium nitride, or any combination thereof.

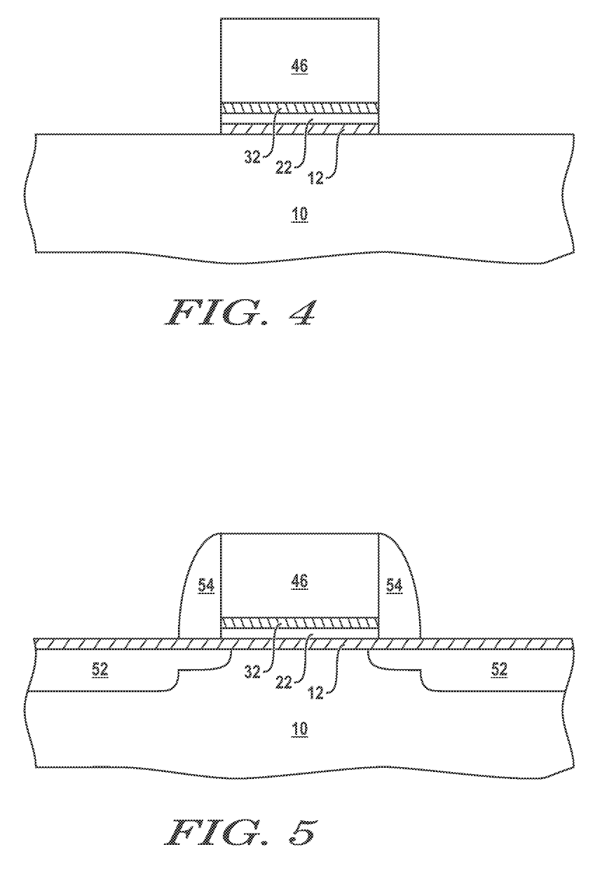

FIG. 4 includes an illustration of a cross-sectional view after patterning the conductive layer 36 to a form a gate electrode 46. In a particular embodiment, the gate electrode 46 can be a control gate electrode of a nonvolatile memory cell. A mask (not illustrated) can be formed over the conductive layer 36 and patterned. The patterned mask can include a feature (not illustrated) that overlies the conductive layer 36 where the gate electrode 46 is to be formed. The conductive layer 36 can be etched using a conventional or proprietary etch tailored for the particular material of the conductive layer 36.

The etch sequence can be continued to etch through the insulating layer 32 and the silicon nitride layer 22, stopping on or within the insulating layer 12. The insulating layer 32 can be etched using a conventional or proprietary etch tailored for the particular material of the insulating layer 32. If the insulating layer 32 includes SiO₂, a conventional or proprietary SiO₂ etching technique can be used.

Although the silicon nitride layer 22 includes boron, the boron concentration may not be high enough to significantly affect the etching, as compared to etching stoichiometric silicon nitride. Thus, the silicon nitride layer 22 can be etched using a conventional or proprietary Si₃N₄ etch for stoichiometric amorphous Si₃N₄.

The etching operation to form the structure in accordance with the embodiment illustrated in FIG. 4 can be formed using a set of actions as part of an etch sequence. Each portion within the sequence may be performed as a timed etch, an endpoint etch, or any combination thereof. For example, the etch of the conductive layer 36 may include a break-through portion to remove any surface oxide or other contaminants on the surface of the conductive layer 36 not covered by the patterned mask, a bulk etch portion for removing most of the thickness of the conductive layer 36, an endpoint portion for detecting when the insulating layer 32 becomes exposed, and an overetch portion to ensure that the conductive layer 36 has been removed except where features, such as the gate electrode 46, are formed. Etch chemistries or etch monitoring may be changed between the actions. The insulating layer 32 and the silicon nitride layer 22 may be etched using similar techniques. Because the insulating layer 32 and the silicon nitride layer 22 are significantly thinner than the conductive layer 36, etching of the insulating layer 32 and the silicon nitride layer 22 may be performed as timed etches in a particular, non-limiting embodiment.

Spacers 54 are formed adjacent to the sides of the gate electrode 46. Source/drain regions 52 are formed within the substrate 10 after forming the gate electrode 46. Parts of the source/drain regions 52 can be formed before or after formation of the spacers 54. Each source/drain regions 52 can include extension regions formed before forming the spacers 54 and heavily doped regions (dopant concentration of at least 1E19 atoms/cm³) formed after forming the spacers 54. Although not illustrated, other dopants can be introduced during the doping sequence. For example, halo regions (not illustrated) can be formed by implanting appropriate ions before forming the spacers 54. The source/drain regions 52 have a conductivity type opposite that of the substrate 10, and the halo regions have a conductivity type that is the same as the substrate 10. The formation of the spacers and the source/drain regions 52 can be performed using a conventional or proprietary technique.

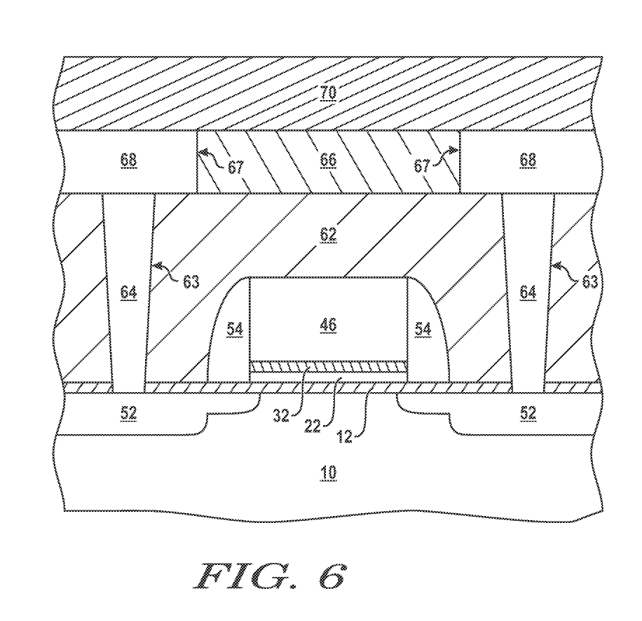

FIG. 6 includes an illustration of a cross-sectional view of a substantially completed electronic device. An interlevel dielectric (“ILD”) layer 62 can be formed over the workpiece. The ILD layer 62 can include a single film or a plurality of films. The films can include an oxide, a nitride, an oxynitride, or any combination thereof In a particular embodiment, the ILD layer 62 can be deposited and planarized using a polishing or etch-back technique. The ILD layer 62 can be patterned to form contact openings 63 that extend through the ILD layer 62 and the insulating layer 22 to expose portions of the source/drain regions 52. Conductive plugs 64 can include silicon, tungsten, or the like and are formed by depositing the material form the conductive plugs 64 and removing portions that overlie the uppermost surface of the ILD layer 62. A barrier layer, an adhesion layer, or both may be formed before depositing the principal material for the conductive plugs 64. A conductive plug can be formed that is electrically connected to the gate electrode 46 but is not illustrated.

Another IDL layer 66 can be formed using any of the materials or techniques, as described with respect to the ILD layer 62. The composition and formation of the ILD layer 66 may be the same as or different from the ILD layer 62. The ILD layer 66 can be patterned to form interconnect trenches 67 that extend through the ILD layer 66 to expose portions of the conductive plugs 64. Interconnects 68 can include copper, aluminum, or the like and are formed by depositing the material from the interconnects 68 and removing portions that overlie the uppermost surface of the ILD layer 66. A barrier layer, an adhesion layer, or both may be formed before depositing the principal material for the interconnects 68.

Although not illustrated, an additional ILD layers and interconnects at another level may be formed if needed or desired. After forming all of the ILDs and interconnect levels, an encapsulating layer 70 is then formed over the interconnects, including the interconnects 68. The encapsulating layer 70 can include a single film or a plurality of films. The encapsulating layer 70 can include an inorganic material, such as a silicon oxide, a silicon nitride, a silicon oxynitride, or any combination thereof The encapsulating layer 70 can include a conventional or proprietary composition and be formed using a conventional or proprietary deposition technique.

Embodiments as described herein may be used to form a silicon nitride layer 22 having grains, and thus, the silicon nitride layer 22 is not completely amorphous. The presence of the boron within the silicon nitride layer 22 can help with the formation of the grains. While the use of boron in grains is known in the non-analogous arts of nuclear energy and recording industries, skilled artisans will appreciate that boron is a dopant in the semiconductor industry.

The grains may allow the charge to be more deeply trapped within the silicon nitride layer 22. Memory cells formed with the silicon layer 22 may be less susceptible to disturb errors, such as program, erase, or read disturb errors. The programming and erasing of the memory cells with the silicon nitride layer 22 may not be affected. For example, when programming is performed by hot electron injection, the control gate may be at a voltage of approximately 8 volts to approximately 10 volts, the drain may be at approximately 4 volts to approximately 6 volts, and the source may be at a voltage in a range of approximately 0 volt to approximately 1 volt.

When erasing is performed by hot hole injection, the control gate may be at a voltage of approximately −5 volts to approximately −7 volts, the drain may be at approximately 4 volts to approximately 6 volts, and the source may be allowed to electrically float. Because hot holes are used for erasing in this embodiment, the electrical conditions may not be significantly different from an embodiment in which an amorphous, stoichiometric silicon nitride layer is used.

When programming or erasing is performed, a larger differential in voltages between the control gate and any of the source, drain, channel (body) or any combination thereof may need to be higher when Fowler-Nordheim tunneling is used. After reading this specification, skilled artisans will be able to determine which programming technique and voltages can be used to meets the needs or desires for a particular memory cell.

The formation and patterning of the silicon nitride layer 22 are relatively straightforward. For chemical vapor deposition, the different choices for the boron-containing and other gases allow skilled artisans to use a deposition process that achieves the desired characteristics for boron concentration, deposition rate, sufficiently low particle counts, or the like. For physical vapor deposition, the target can include a composition that matches the desired characteristics, such as grain size, concentration of boron or grains, or the like. In one embodiment, the boron concentration is substantially uniform throughout the thickness of the silicon nitride layer 22. Even if a small amount of boron is drawn into the insulating layer 12 or 32 at the interfaces with the silicon nitride layer 22, substantially all of the boron within the silicon nitride layer 22 away from the interfaces may be substantially uniformly distributed throughout the silicon nitride layer 22. The etching of the silicon nitride layer 22 can be similar to etching amorphous, stoichiometric silicon nitride.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a process of forming an electronic device can include forming a first insulating layer over a substrate, and forming a boron-containing silicon nitride layer over the insulating layer.

In an embodiment of the first aspect, the process further includes forming a second insulating layer over the boron-containing silicon nitride layer, and forming a control gate electrode layer over the second insulating layer. In another embodiment, forming the boron-containing silicon nitride layer includes placing the substrate and first insulating layer into a chamber, introducing a nitrogen-containing gas into the chamber, introducing a silicon-containing gas into the chamber, and introducing a boron-containing gas into the chamber.

In a particular embodiment of the first aspect, the nitrogen-containing gas includes molecular nitrogen, ammonia, hydrazine, or any combination thereof, the silicon-containing gas includes SiₐH_{b}X_{c}, wherein X is a halogen, a is 1 to 3, (b+c)=(2a+2), and b or c is in a range of 0 to 2a+2, and the boron-containing gas includes B_{d}HₑX_{f}, wherein X is a halogen, a is 1 or 2, (e+f)=3d, and e or f is in a range of 0 to 3d. In another particular embodiment, the boron-containing gas includes diborane, boron tribromide, boron trichloride, or any combination thereof. In still another particular embodiment, the nitrogen-containing gas is ammonia, the silicon-containing gas is dichlorosilane, and the boron-containing gas is diborane. In a further particular embodiment, forming the boron-containing silicon nitride layer includes chemical vapor depositing the boron-containing silicon nitride layer without plasma assistance. In still a further particular embodiment, forming the boron-containing silicon nitride layer includes chemical vapor depositing the boron-containing silicon nitride layer with plasma assistance. In yet another embodiment, forming the boron-containing silicon nitride layer includes physical vapor depositing the boron-containing silicon nitride layer.

In a second aspect, an electronic device can include a substrate and a boron-containing silicon nitride layer.

In an embodiment of the second aspect, the electronic device includes a nonvolatile memory cell, and a charge storage layer within the nonvolatile memory cell includes the boron-containing silicon nitride layer. In a particular embodiment, the electronic device further includes a control gate electrode, a first insulating layer disposed between the substrate and the boron-containing silicon nitride layer, and a second insulating layer disposed between the boron-containing silicon nitride layer and the control gate electrode. In a more particular embodiment, the electronic device further includes a first source/drain region adjacent to a first side of the control gate electrode, and a second source/drain region spaced apart from the first source/drain region and adjacent to a second side of the control gate electrode, wherein the second side is opposite the first side.

In another embodiment of the second aspect, the boron-containing silicon nitride layer includes no greater than approximately 9 atomic % boron. In a particular embodiment, the boron-containing silicon nitride layer includes no greater than approximately 5 atomic % boron. In a further embodiment, the boron-containing silicon nitride layer has approximately 3.0 atoms of silicon for every 4.0 atoms of nitrogen. In still a further embodiment, the boron-containing silicon nitride layer includes grains.

In a third aspect, an electronic device can include a substrate, and a silicon nitride layer having grains.

In an embodiment of the third aspect, the silicon nitride layer includes no greater than approximately 9 atomic % boron. In another embodiment, the electronic device includes a nonvolatile memory cell, and the nonvolatile memory cell includes a control gate electrode, a charge storage layer that includes the silicon nitride layer, a first insulating layer disposed between the substrate and the silicon nitride layer, and a second insulating layer disposed between the silicon nitride layer and the control gate electrode.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. A process of forming an electronic device including a nonvolatile memory cell, the process comprising:
forming a first insulating layer over a substrate within the nonvolatile memory cell; and
forming a charge storage layer over the insulating layer within the nonvolatile memory cell, the charge storage layer including a boron-containing silicon nitride layer, wherein the boron-containing silicon-nitride layer includes no greater than approximately 9 atomic % boron.

2. The process of claim 1, further comprising:
forming a second insulating layer over the boron-containing silicon nitride layer; and
forming a control gate electrode layer over the second insulating layer.

3. The process of claim 1, wherein forming the boron-containing silicon nitride layer comprises:
placing the substrate and first insulating layer into a chamber;
introducing a nitrogen-containing gas into the chamber;
introducing a silicon-containing gas into the chamber; and
introducing a boron-containing gas into the chamber.

4. The process of claim 3, wherein:
the nitrogen-containing gas includes molecular nitrogen, ammonia, hydrazine, or any combination Thereof;
the silicon-containing gas includes SiₐH_{b}X_{c}, wherein X is a halogen, a is 1 to 3, (b+c)=(2a+2), and b or c is in a range of 0 to 2a+2; and
the boron-containing gas includes B_{d}HₑX_{f}, wherein X is a halogen, d is 1 or 2, (e+f) =3d, and e or f is in a range of 0 to 3d.

5. The process of claim 4, wherein the boron-containing gas includes diborane, boron tribromide, boron trichloride, or any combination thereof.

6. The process of claim 4, wherein:
the nitrogen-containing gas is ammonia;
the silicon-containing gas is dichlorosilane; and
the boron-containing gas is diborane.

7. The process of claim 4, wherein forming the boron-containing silicon nitride layer comprises chemical vapor depositing the boron-containing silicon nitride layer without plasma assistance.

8. The process of claim 4, wherein forming the boron-containing silicon nitride layer comprises chemical vapor depositing the boron-containing silicon nitride layer with plasma assistance.

9. The process of claim 1, wherein forming the boron-containing silicon nitride layer comprises physical vapor depositing the boron-containing silicon nitride layer.

10. An electronic device comprising:
a nonvolatile memory cell, including:
a substrate; and
a charge storage layer including a boron-containing silicon nitride layer, wherein the boron-containing silicon-nitride layer includes no greater than approximately 9 atomic % boron.

11. (canceled)

12. The electronic device of claim 10, further comprising:
a control gate electrode;
a first insulating layer disposed between a substrate and the boron-containing silicon nitride layer; and
a second insulating layer disposed between the boron-containing silicon nitride layer and the control gate electrode.

13. The electronic device of claim 12, further comprising:
a first source/drain region adjacent to a first side of the control gate electrode; and
a second source/drain region spaced apart from the first source/drain region and adjacent to a second side of the control gate electrode, wherein the second side is opposite the first side.

14. (canceled)

15. The electronic device of claim 10, wherein the boron-containing silicon nitride layer comprises no greater than approximately 5 atomic % boron.

16. The electronic device of claim 10, wherein the boron-containing silicon nitride layer has approximately 10 atoms of silicon for every 4.0 atoms of nitrogen.

17. The electronic device of claim 10, wherein the boron-containing silicon nitride layer includes grains.

18. An electronic device comprising:
a nonvolatile memory cell including:
a substrate; and
a silicon nitride layer having a solid structure that includes grains and an amorphous portion.

19. The electronic device of claim 18, wherein the silicon-nitride layer includes boron and comprises no greater than approximately 9 atomic % boron..

20. The electronic device of claim 18, wherein:
the nonvolatile memory cell comprises:
a control gate electrode;
a charge storage layer that comprises the silicon nitride layer; and
a first insulating layer disposed between the substrate and the silicon nitride layer; and
a second insulating layer disposed between the silicon nitride layer and the control gate electrode.
